(19) United States
(12) Patent Application Publication
(10) Pub. No.: US 2007/0210458 A1
(43) Pub. Date: Sep. 13, 2007

(54) SEMICONDUCTOR DEVICE AND METHOD FOR MANUFACTURING SEMICONDUCTOR DEVICE

(75) Inventor: Yoshinori HAGIO, Hiratsuka-shi (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/682,509

(22) Filed: Mar. 6, 2007

(30) Foreign Application Priority Data
Mar. 7, 2006 (JP) 2006-060898

(51) Int. Cl. H01L 23/52

(52) U.S. Cl. 257/784

(57) ABSTRACT

A semiconductor device includes a base plate including a plurality of terminals; a semiconductor chip, mounted above the base plate, including a plurality of pads arranged on a face of the semiconductor chip; an insulating slope member, disposed around the semiconductor chip, covering steps between the semiconductor chip and the base plate; and a wiring pattern extending on the insulating slope member to electrically connect the terminals to the pads. The base plate has a base-side retaining section for retaining the insulating slope member.

### BACKGROUND

1. Technical Field

Several aspects of the present invention relate to a semiconductor device and a method for manufacturing such a semiconductor device.

2. Related Art

Known semiconductor devices include base plates and semiconductor chips mounted on the base plates. Japanese Unexamined Patent Application Publication No. 2005-302765 discloses a semiconductor device. FIG. 16A shows a semiconductor device 101. With reference to FIG. 16A, the semiconductor device 101 includes a base plate 102 including a plurality of terminals 102a; a semiconductor chip 103, mounted on the base plate 102, including a plurality of pads 103a arranged on the upper face 103b of the semiconductor chip 103; an insulating slope member 104, located around the semiconductor chip 103, covering steps between the semiconductor chip 103 and the base plate 102; and a wiring pattern 105 extending on the insulating slope member 104 to electrically connect the terminals 102a to the pads 103a.

The semiconductor device 101 is manufactured by a method described below. The semiconductor chip 103 is mounted on the base plate 102 as shown in FIG. 16B. The insulating slope member 104 is provided around the semiconductor chip 103 as shown in FIG. 16C. In order to form the insulating slope member 104, a coating solution is prepared by dissolving an insulating material for forming the insulating slope member 104 in a solvent and then applied onto a region surrounding the semiconductor chip 103 by a droplet-ejecting process and the applied coating solution is dried. The application and drying of the coating solution are repeated several times, whereby the insulating slope member 104 is formed so as to cover the steps between the semiconductor chip 103 and the base plate 102 as shown in FIGS. 16A and 16C. The wiring pattern 105 is then formed by a droplet-ejecting process, whereby the semiconductor device 101 is obtained as shown in FIG. 16A.

In the manufacturing method, since the droplet-ejecting process is used, the coating solution needs to have a relatively small viscosity. A reduction in the viscosity of the coating solution can cause a problem in that the coating solution spreads unevenly over the base plate 102 as shown in FIGS. 16C and 16D. Since the insulating slope member 104 is formed by drying the coating solution spreading unevenly, the insulating slope member 104 has a slope having portions with different angles. This can cause breakages in the wiring pattern 105.

Since silicon that is a material for forming the semiconductor chip 103 is exposed at a marginal portion of the upper face 103b of the semiconductor chip 103, the insulating slope member 104 should be formed so as to cover the exposed silicon. However, since the coating solution has a small viscosity and therefore spreads unevenly over the base plate 102, the marginal portion of the upper face 103b of the semiconductor chip 103 is partly exposed from the insulating slope member 104. If the wiring pattern 105 is disposed on the partly uncovered marginal portion of the upper face 103b thereof, a short circuit will be caused between the wiring pattern 105 and the semiconductor chip 103.

### SUMMARY

An advantage of an aspect of the invention is to provide a semiconductor device including an insulating slope member having an appropriate shape. An advantage of another aspect of the invention is to provide a method for manufacturing such a semiconductor device.

A semiconductor device according to the present invention includes a base plate including a plurality of terminals; a semiconductor chip, mounted above the base plate, including a plurality of pads arranged on a face of the semiconductor chip; an insulating slope member, disposed around the semiconductor chip, covering steps between the semiconductor chip and the base plate; and a wiring pattern extending on the insulating slope member to electrically connect the terminals to the pads. The base plate has a base-side retaining section for retaining the insulating slope member.

In the semiconductor device, the base-side retaining section preferably has a groove or bumps.

In the semiconductor device, the base-side retaining section is preferably disposed between the terminals and the pads.

According to the semiconductor device, since the base plate has the base-side retaining section for retaining the insulating slope member, the insulating slope member is prevented from spreading and has an appropriate shape, that is, the insulating slope member has no portions with different tilt angles, thereby preventing the wiring pattern from being broken.

Furthermore, since the insulating slope member has such an appropriate shape, the insulating slope member completely covers a marginal portion of the semiconductor chip. This prevents a short circuit from being caused between the wiring pattern and the semiconductor chip.

Another semiconductor device according to the present invention includes a base plate including a plurality of terminals; a semiconductor chip, mounted above the base plate, including a plurality of pads arranged on a face of the semiconductor chip; an insulating member, disposed around the semiconductor chip, covering steps between the semiconductor chip and the base plate; and a wiring pattern extending on the insulating slope member to electrically connect the terminals to the pads. The base plate has a recessed section for accommodating the semiconductor chip and the insulating member.

In this semiconductor device, the recessed section preferably has a depth less than or equal to the thickness of the semiconductor chip.

According to this semiconductor device, since this base plate has the recessed section for accommodating this semiconductor chip and the insulating member, this semiconductor chip is fixed in the recessed section with the insulating member and the insulating member has an appropriate shape, that is, the insulating member has no portions with different tilt angles, thereby preventing this wiring pattern from being broken.

Furthermore, since the insulating member has such an appropriate shape, the insulating member completely covers a marginal portion of this semiconductor chip. This prevents a short circuit from being caused between this wiring pattern and this semiconductor chip.

Another semiconductor device according to the present invention includes a base plate including a plurality of terminals; a semiconductor chip, mounted above the base plate, including a plurality of pads arranged on a face of the semiconductor chip; an insulating slope member, disposed around the semiconductor chip, covering steps between the semiconductor chip and the base plate; and a wiring pattern extending on the insulating slope member to electrically connect the terminals to the pads. The semiconductor chip has a side face which is adjacent to the insulating slope member and which is tilted or stepped and the insulating slope member is disposed on the side face of the insulating slope member.

According to this semiconductor device, since the side face of this insulating slope member is tilted or stepped, this insulating slope member is prevented from spreading and has an appropriate shape, that is, this insulating slope member has no portions with different tilt angles, thereby preventing this wiring pattern from being broken.

Furthermore, since this insulating slope member has such an appropriate shape, this insulating slope member completely covers a marginal portion of this semiconductor chip. This prevents a short circuit from being caused between this wiring pattern and this semiconductor chip.

Another semiconductor device according to the present invention includes a base plate including a plurality of terminals; a semiconductor chip, mounted above the base plate, including a plurality of pads arranged on a face of the semiconductor chip; an insulating slope member, disposed around the semiconductor chip, covering steps between the semiconductor chip and the base plate; and a wiring pattern extending on the insulating slope member to electrically connect the terminals to the pads. The semiconductor chip has a chip-side retaining section, disposed on the face of the semiconductor chip, for retaining the insulating slope member.

In this semiconductor device, the base-side retaining section preferably has a groove or bumps.

In this semiconductor device, the chip-side retaining section preferably has a guard ring disposed on the face of the semiconductor chip.

In this semiconductor device, the base-side retaining section is preferably located outside the pads.

According to this semiconductor device, since this semiconductor chip has the chip-side retaining section for retaining this insulating slope member, this insulating slope member completely covers a marginal portion the face of this semiconductor chip. This insulating slope member has an appropriate shape, that is, this insulating slope member has no portions with different tilt angles, thereby preventing this wiring pattern from being broken.

Furthermore, since this insulating slope member has such an appropriate shape and completely covers the marginal portion of this semiconductor chip, a short circuit is prevented from being caused between this wiring pattern and this semiconductor chip.

A method for manufacturing a semiconductor device according to the present invention includes mounting a semiconductor chip including a plurality of pads above a base plate including a plurality of terminals, the pads being arranged on a face of the semiconductor chip; forming an insulating slope member around the semiconductor chip such that the insulating slope member covers steps between the semiconductor chip and the base plate; and forming a wiring pattern on the insulating slope member such that the wiring pattern electrically connects the terminals to the pads. The base plate has a base-side retaining section for retaining the insulating slope member and the insulating slope member is retained by the base-side retaining section when the insulating slope member is formed.

Another method for manufacturing a semiconductor device according to the present invention includes mounting a semiconductor chip including a plurality of pads above a base plate including a plurality of terminals, the pads being arranged on a face of the semiconductor chip; forming an insulating member around the semiconductor chip such that the insulating member covers steps between the semiconductor chip and the base plate; and forming a wiring pattern on the insulating member such that the wiring pattern electrically connects the terminals to the pads. The base plate has a recessed section for accommodating the semiconductor chip and the insulating member and the insulating member is provided in a gap between the recessed section and the semiconductor chip.

Another method for manufacturing a semiconductor device according to the present invention includes mounting a semiconductor chip including a plurality of pads above a base plate including a plurality of terminals, the pads being arranged on a face of the semiconductor chip; forming an insulating slope member around the semiconductor chip such that the insulating slope member covers steps between the semiconductor chip and the base plate; and forming a wiring pattern on the insulating slope member such that the wiring pattern electrically connects the terminals to the pads. The semiconductor chip has a side face which is adjacent to the insulating slope member and which is tilted or stepped and the insulating slope member is disposed on the side face of the insulating slope member.

Another method for manufacturing a semiconductor device according to the present invention includes mounting a semiconductor chip including a plurality of pads above a base plate including a plurality of terminals, the pads being arranged on a face of the semiconductor chip; forming an insulating slope member around the semiconductor chip such that the insulating slope member covers steps between the semiconductor chip and the base plate; and forming a wiring pattern on the insulating slope member such that the wiring pattern electrically connects the terminals to the pads. The semiconductor chip has a chip-side retaining section, disposed on the face of the semiconductor chip, for retaining the insulating slope member and the insulating slope member is retained by the chip-side retaining section when the insulating slope member is formed.

According to any one of the above methods, the insulating slope member is prevented from spreading; hence the insulating slope member has an appropriate shape, that is, the insulating slope member has no portions with different tilt angles, thereby preventing the wiring pattern from being broken.

Furthermore, since the insulating slope member has such an appropriate shape and completely covers a marginal portion of the upper face of the semiconductor chip, a short circuit is prevented from being caused between the wiring pattern and the semiconductor chip.

### BRIEF DESCRIPTION OF THE DRAWINGS

The invention will be described with reference to the accompanying drawings, wherein like numbers reference like elements.

FIG. 1A is a schematic plan view of a semiconductor device according to a first embodiment of the present invention, FIG. 1B is a schematic sectional view of the semiconductor device taken along the line IB-IB of FIG. 1A, and FIG. 1C is an enlarged sectional view of a principal part of the semiconductor device.

FIGS. 2A to 2D are illustrations showing steps included in a method for manufacturing the semiconductor device shown in FIG. 1A.

FIG. 3 is an enlarged sectional view of a modification of the semiconductor device according to the first embodiment.

FIGS. 4A and 4B are illustrations showing steps included in a method for manufacturing the modification of the semiconductor device according to the first embodiment.

FIG. 5A is a schematic plan view of a semiconductor device according to a second embodiment of the present invention and FIG. 5B is a schematic sectional view of this semiconductor device taken along the line VB-VB of FIG. 5A.

FIGS. 6A to 6C are illustrations showing steps included in a method for manufacturing the semiconductor device shown in FIG. 5A.

FIG. 7 is a schematic enlarged sectional view of a modification of the semiconductor device according to the second embodiment.

FIG. 8 is an enlarged sectional view of a semiconductor device according to a third embodiment of the present invention.

FIG. 9 is an enlarged sectional view of a modification of the semiconductor device according to the third embodiment.

FIG. 10 is an enlarged sectional view of a semiconductor device according to a fourth embodiment of the present invention.

FIG. 11 is an illustration showing a step included in a method for manufacturing the semiconductor device shown in FIG. 10.

FIG. 12 is an enlarged sectional view of a modification of the semiconductor device according to the fourth embodiment.

FIG. 13 is an illustration showing a step included in a method for manufacturing the modification shown in FIG. 12.

FIG. 14 is an illustration of a notebook-type personal computer that is an example of an electronic apparatus including the semiconductor device according to any one of the first to fourth embodiments.

FIG. 15 is an illustration of a mobile phone that is another example of the electronic apparatus.

FIG. 16A is an enlarged sectional view of a known semiconductor device and FIGS. 16B to 16D are illustrations showing steps included in a method for manufacturing the known semiconductor device.

### DESCRIPTION OF EXEMPLARY EMBODIMENTS

### First Embodiment

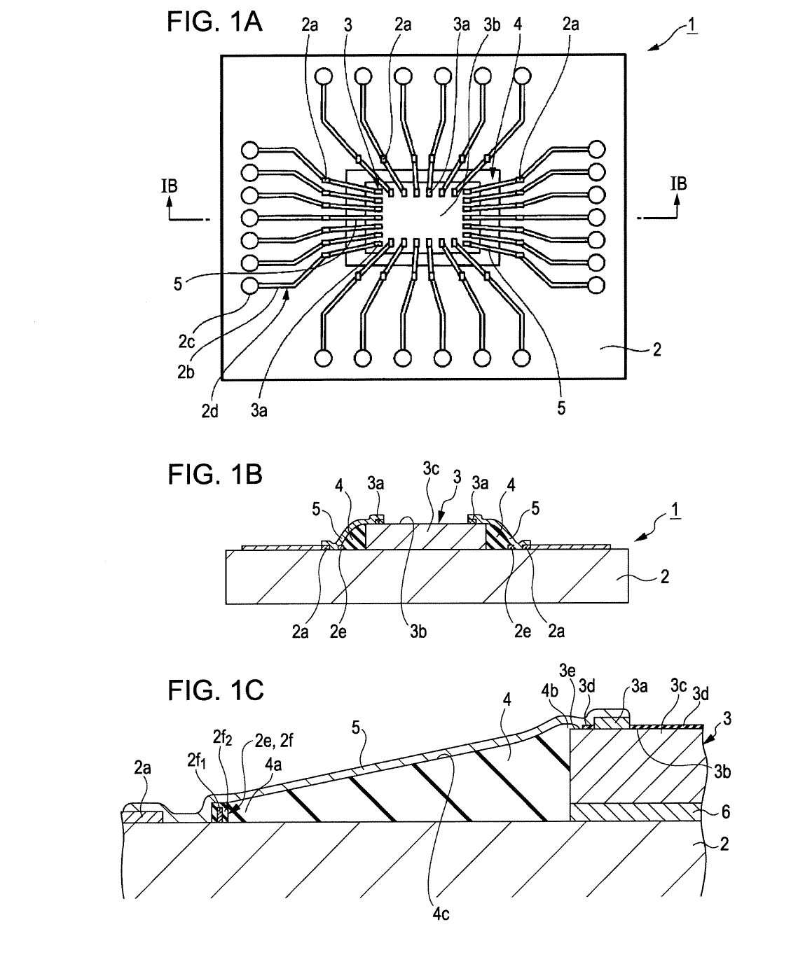

A semiconductor device according to a first embodiment of the present invention will now be described with reference to the accompanying drawings. FIG. 1A is a schematic plan view of the semiconductor device, FIG. 1B is a schematic sectional view of the semiconductor device taken along the line IB-IB of FIG. 1A, and FIG. 1C is an enlarged sectional view of a principal part of the semiconductor device. The drawings are used to show the configuration of the semiconductor device; hence, the relative dimensions of components shown in the drawings can be different from those of components of an actual semiconductor device.

With reference to FIG. 1A, the semiconductor device is represented by reference numeral 1 and includes a base plate 2 including a plurality of terminals 2a; a semiconductor chip 3, mounted above the base plate 2, including a plurality of pads 3a arranged on a first face 3b of the semiconductor chip 3; an insulating slope member 4, disposed around the semiconductor chip 3, covering steps between the semiconductor chip 3 and the base plate 2; and a wiring pattern 5 extending on the insulating slope member 4 to electrically connect the terminals 2a to the pads 3a.

The base plate 2 is not particularly limited in material or structure. Any known substrate can be used as the base plate 2. The base plate 2 may be flexible or rigid. The base plate 2 may have a single-layer or multilayer structure. The base plate 2 may contain wiring lines which are not shown. Furthermore, the base plate 2 is not particularly limited in shape.

The terminals 2a are arranged on the base plate 2. The terminals 2a are electrically connected to external terminals 2c with leads 2b. The terminals 2a, the leads 2b, and the external terminals 2c are collectively referred to as a base-side wiring pattern 2d. The base-side wiring pattern 2d is made of copper foil or the like.

The base plate 2 has a base-side retaining section 2e disposed thereon. The base-side retaining section 2e is located between the terminals 2a and the semiconductor chip 3. The base-side retaining section 2e includes bumps 2f. With reference to FIG. 1C, the bumps 2f include respective metal portions 2f1 and respective insulating portions 2f2 covering the metal portions 2f1. The metal portions 2f1 are arranged around the semiconductor chip 3 and have substantially a circular shape in plan view. The metal portions 2f1, as well as the base-side wiring pattern 2d, are made of copper foil or the like. The insulating portions 2f2 are made of a solder resist or the like. The bumps 2f have a width of about 10 to 100 μm and a height of about 5 to 15 μm. When the height of the bumps 2f is 5 μm or more, the bumps 2f can securely retain the insulating slope member 4.

The semiconductor chip 3 further includes a main body section 3c made of single-crystalline silicon doped with an impurity or the like and an integrated circuit section which is not shown and which is located in the main body section 3c. The integrated circuit section is connected to the pads 3a. The pads 3a are arranged on the first face 3b of the semiconductor chip 3. An insulating layer 3d extends over the first face 3b except the pads 3a and a marginal portion 3e of the first face 3b. The main body section 3c is exposed at the marginal portion 3e thereof. The main body section 3c is made of single-crystalline silicon or the like and has a thickness of about 30 to 50 μm. The integrated circuit section is not particularly limited in configuration and may include, for example, an active element such as a transistor and a passive element such as a resistor, a coil, or a capacitor. The semiconductor chip 3 is mounted above the base plate 2 in such a state that the pads 3a are directed in the direction opposite to the base plate 2. A die attach film 6 with a thickness of about 10 to 20 μm is disposed between the base plate 2 and the semiconductor chip 3. The base plate 2 and the semiconductor chip 3 are joined to each other with the die attach film 6.

The height of the steps between the base plate 2 and the semiconductor chip 3 is equal to the sum of the thickness of the main body section 3c and that of the die attach film 6 and is about 40 to 70 μm.

The insulating slope member 4 is located around the semiconductor chip 3 to cover the steps between the semiconductor chip 3 and the base plate 2. With reference to FIG. 1C, the insulating slope member 4 has a first end portion 4a retained by the bumps 2f and a second end portion 4b covering the marginal portion 3e of the semiconductor chip 3. The insulating slope member 4 further has a slope 4c located between the first and second end portions 4a and 4b. The insulating slope member 4 is made of an insulating resin such as an epoxy resin and can be formed by, for example, a droplet-ejecting process.

The wiring pattern 5 extends on the slope 4c to electrically connect the terminals 2a to the pads 3a. A material for forming the wiring pattern 5 is not particularly limited and the wiring pattern 5 may be made of a known material. The wiring pattern 5 may include stacked layers each made of copper (Cu), chromium (Cr), titanium (Ti), nickel (Ni), titanium-tungsten (Ti—W), gold (Au), aluminum (Al), nickel-vanadium (Ni—V), or tungsten (W) or a single layer made of one of these materials. The wiring pattern 5 can be formed by, for example, a droplet-ejecting process.

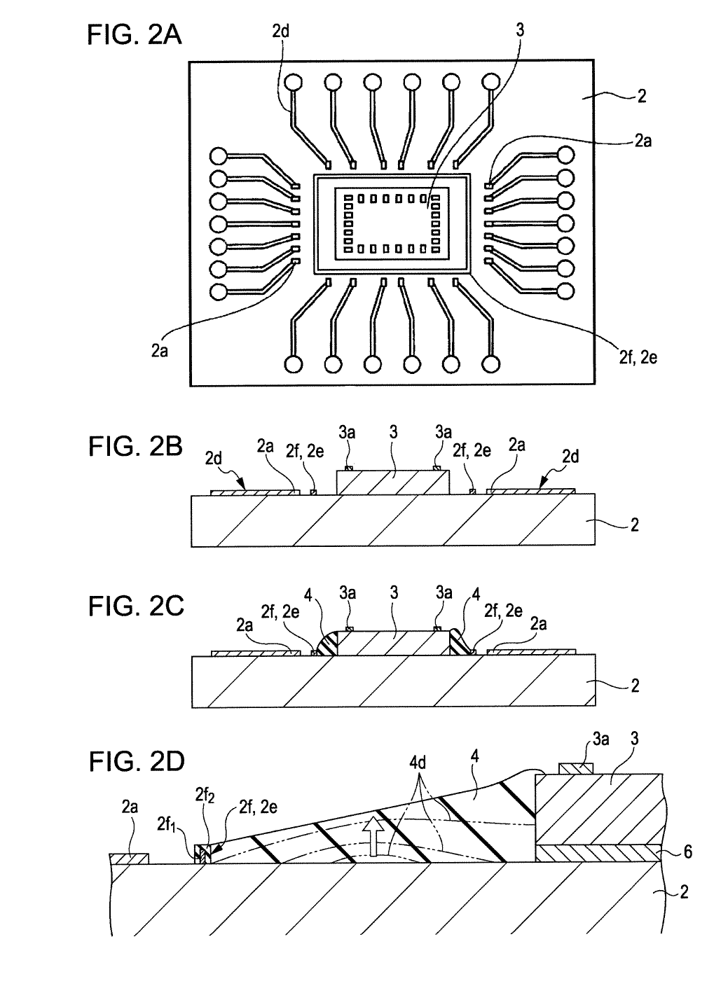

A method for manufacturing the semiconductor device 1 will now be described. FIGS. 2A to 2D are illustrations showing steps included in the method.

As shown in FIGS. 2A and 2B, in a first step, the base-side wiring pattern 2d and the bumps 2f are formed on the base plate 2 and the semiconductor chip 3 is then provided at substantially the center of a region surrounded by the bumps 2f.

As shown in FIG. 2C, in a second step, the insulating slope member 4 is formed around the semiconductor chip 3 so as to cover the steps between the semiconductor chip 3 and the base plate 2.

The insulating slope member 4 can be formed by, for example, a droplet-ejecting process. A procedure for forming the insulating slope member 4 by the droplet-ejecting process is as follows: a coating solution is prepared by dissolving an insulating material for forming the insulating slope member 4 in a solvent and then applied onto a region surrounding the semiconductor chip 3 using a droplet-ejecting head and the applied coating solution is dried. The application and drying of the coating solution are repeated several times, whereby the insulating material 4d is grown as shown in FIG. 2D. This allows the insulating slope member 4 to cover the steps between the semiconductor chip 3 and the base plate 2. The insulating material 4d is retained by the bumps 2f and therefore prevented from spreading outside the region surrounded by the bumps 2f. Since the insulating material 4d is prevented from spreading outside the region surrounded by the bumps 2f, the insulating material 4d is grown to cover the marginal portion 3e of the semiconductor chip 3. The insulating slope member 4 is obtained as described above.

In a third step, the wiring pattern 5 is formed by a droplet-ejecting process, whereby the semiconductor device 1 is obtained as shown in FIG. 1.

In the semiconductor device 1, since the bumps 2f are arranged on the base plate 2 so as to retain the insulating slope member 4, the insulating slope member 4 is prevented from extending beyond the bumps 2f to the terminals 2a and therefore has an appropriate shape. That is, the first end portion 4a of the insulating slope member 4 extends along an array of the bumps 2f; hence, the first end portion 4a of the insulating slope member 4, that is, the outline of the insulating slope member 4 is straight when viewed from above, whereas an end portion of an insulating slope member formed by a conventional technique is nonuniform. This allows the insulating slope member 4 to have such a shape in cross section as shown in FIG. 1C; hence, the slope 4c is flat and has no portions with different tilt angles but has a constant angle.

Since the presence of the bumps 2f allows the slope 4c to be flat and to have a constant angle, the wiring pattern 5 disposed on the slope 4c can be prevented from being broken.

Since the insulating slope member 4 is prevented from extending beyond the bumps 2f to the terminals 2a, the second end portion 4b of the insulating slope member 4 can completely cover the marginal portion 3e of the first face 3b of the semiconductor chip 3. Although the main body section 3c of the semiconductor chip 3 that is made of single-crystalline silicon is exposed at the marginal portion 3e thereof before the insulating slope member 4 is formed, the exposed main body section 3c is covered with the second end portion 4b of the insulating slope member 4. This prevents a short circuit from being caused between the wiring pattern 5 and the semiconductor chip 3.

Since the insulating slope member 4 is prevented from extending beyond the bumps 2f to the terminals 2a, the bumps 2f can be formed close to the semiconductor chip 3 such that an area occupied by the insulating slope member 4 is reduced. This leads to a reduction in the distance between the semiconductor chip 3 and the terminals 2a, resulting in a reduction in the size of the semiconductor device 1.

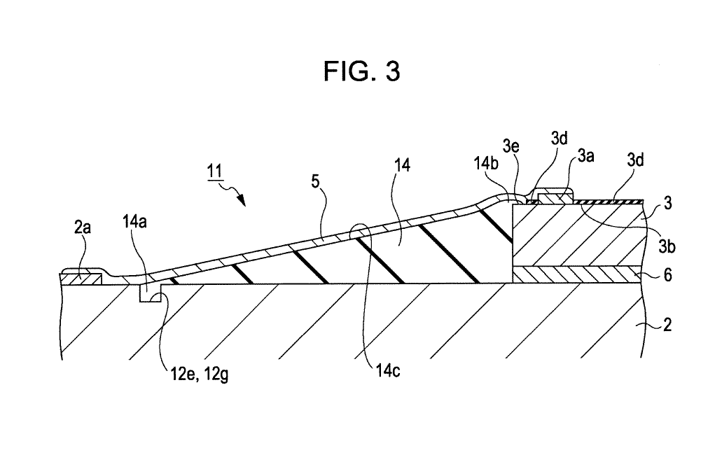

Modifications of the semiconductor device 1 of this embodiment will now be described with reference to the accompanying drawings. FIG. 3 is an enlarged sectional view of a semiconductor device 11 that is a modification of the semiconductor device 1 of this embodiment.

This semiconductor device 11 shown in FIG. 3 is different from that semiconductor device 1 shown in FIG. 1 in that this semiconductor device 11 includes a base-side retaining section 12e including a groove 12g. Components, included in this semiconductor device 11, other than this base-side retaining section 12e and an insulating slope member 14 are the same as those included in that semiconductor device 1. The same components have the same reference numerals and will not be described in detail.

With reference to FIG. 3, this semiconductor device 11 includes a base plate 2 and this base-side retaining section 12e including the groove 12g lies on the base plate 2 and is located between a semiconductor chip 3 and terminals 2a. The groove 12g has a loop shape and surrounds this semiconductor chip 3. The groove 12g has a width of about 10 to 100 μm and a depth of about 5 to 15 μm. When the groove 12g has a depth of 5 μm or more, this base-side retaining section 12e can securely retain an insulating slope member 14.

This insulating slope member 14 is located around this semiconductor chip 3 and covers steps between this semiconductor chip 3 and this base plate 2. With reference to FIG. 3, this insulating slope member 14 has a first end portion 14a retained in the groove 12g and a second end portion 14b covering a marginal portion 3e of this semiconductor chip 3. This insulating slope member 14 further has a slope 14c located between these first and second end portions 14a and 14b. This insulating slope member 14 is made of an insulating resin such as an epoxy resin and can be formed by, for example, a droplet-ejecting process.

In this semiconductor device 11, since this base plate 2 has this base-side retaining section 12e having the groove 12g retaining this insulating slope member 14, this insulating slope member 14 is prevented from extending beyond the groove 12g to these terminals 2a and therefore has an appropriate shape. That is, the first end portion 14a of this insulating slope member 14 extends along the groove 12g; hence, the first end portion 14a, that is, the outline of this insulating slope member 14 is straight when viewed from above, whereas an end portion of an insulating slope member formed by a conventional technique is nonuniform. This allows this insulating slope member 14 to have such a shape in cross section as shown in FIG. 3; hence, this slope 14c is flat and has no portions with different tilt angles but has a constant angle.

Since the presence of the groove 12g allows this slope 14c to be flat and to have a constant angle, a wiring pattern 5 disposed on this slope 4c can be prevented from being broken.

Since this insulating slope member 14 is prevented from extending beyond the groove 12g to these terminals 2a, the second end portion 14b of this insulating slope member 14 can completely cover the marginal portion 3e of this semiconductor chip 3. This prevents a short circuit from being caused between this wiring pattern 5 and this semiconductor chip 3.

Since this insulating slope member 14 is prevented from extending beyond the groove 12g to these terminals 2a, the groove 12g can be formed close to this semiconductor chip 3 such that an area occupied by this insulating slope member 14 is reduced. This leads to a reduction in the distance between this semiconductor chip 3 and these terminals 2a, resulting in a reduction in the size of this semiconductor device 11.

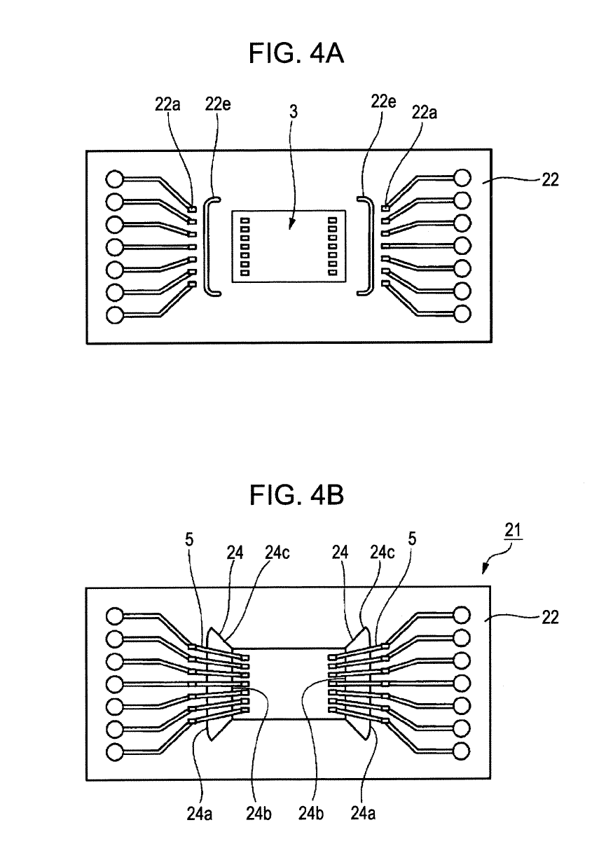

FIGS. 4A and 4B are illustrations showing steps included in a method for manufacturing a semiconductor device 21 that is a modification of the semiconductor device 1 of this embodiment.

This semiconductor device 21 includes a semiconductor chip 3 and a base plate 22 on which terminals 22a are arranged. This semiconductor device 21 is different from that semiconductor device 1 shown in FIG. 1 in that these terminals 22a are located on the right and left sides of this semiconductor chip 3 as shown in FIG. 4A and two base-side retaining sections 22e are each disposed between this semiconductor chip 3 and these terminals 22a located on the right or left side of this semiconductor chip 3, that is, the base-side retaining sections 22e are not arranged to form a circle but are spaced from each other. Components, included in this semiconductor device 21, other than the base-side retaining sections 22e are the same as those included in that semiconductor device 1 shown in FIG. 1. The same components have the same reference numerals and will not be described in detail.

In this semiconductor device 21, since these terminals 22a are located on the right and left sides of this semiconductor chip 3 as shown in FIG. 4A and the base-side retaining sections 22e are disposed between this semiconductor chip 3 and these terminals 22a as described above, the base-side retaining sections 22e are not arranged to form a circle but are spaced from each other. The base-side retaining sections 22e may include bumps or grooves.

With reference to FIG. 4B, insulating slope members 24 are arranged on the right and left sides of this semiconductor chip 3 so as to cover steps between this semiconductor chip 3 and this base plate 22. The insulating slope members 24 have first end portions 24a retained by the base-side retaining sections 22e and second end portions 24b covering parts of a marginal portion of this semiconductor chip 3. The insulating slope members 24 further have slopes 24c located between the first and second end portions 24a and 24b thereof. The insulating slope members 24 are made of an insulating resin such as an epoxy resin and can be formed by, for example, a droplet-ejecting process.

This semiconductor device 21 has the same advantages as those of those semiconductor devices 1 and 11.

### Second Embodiment

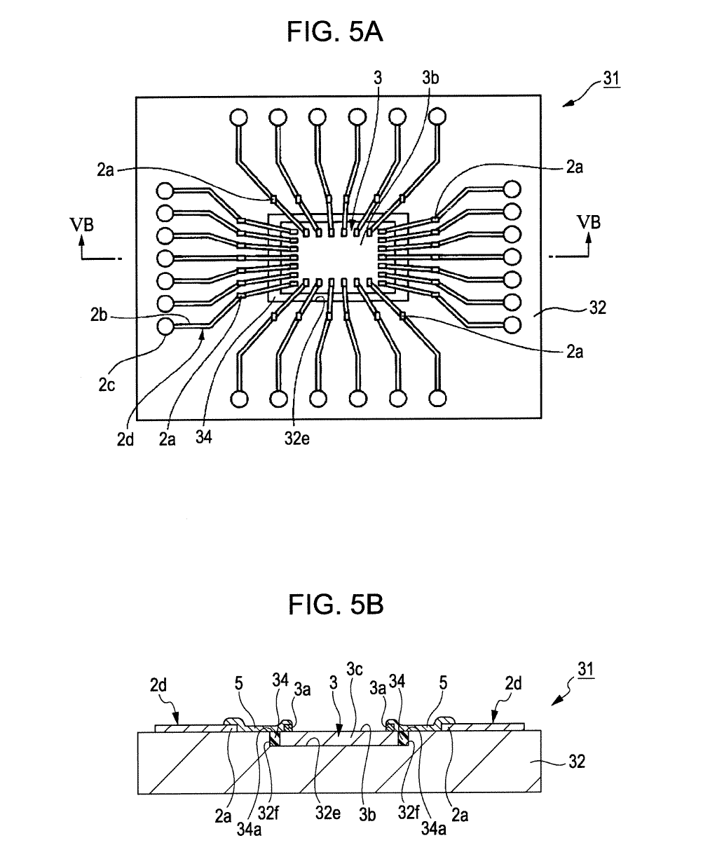

A semiconductor device according to a second embodiment of the present invention will now be described with reference to the accompanying drawings. FIG. 5A is a schematic plan view of the semiconductor device and FIG. 5B is a schematic sectional view of the semiconductor device taken along the line VB-VB of FIG. 5A. Some of components included in the semiconductor device shown in FIGS. 5A and 5B are the same as those shown in FIGS. 1A to 1C. The same components have the same reference numerals and will not be described in detail.

With reference to FIG. 5A, the semiconductor device is represented by reference numeral 31 and includes a base plate 32 including a plurality of terminals 2a; a semiconductor chip 3, mounted on the base plate 32, including a plurality of pads 3a arranged on a first face 3b of the semiconductor chip 3; an insulating member 34, disposed around the semiconductor chip 3, covering steps between the semiconductor chip 3 and the base plate 32; and a wiring pattern 5 extending on the insulating member 34 to electrically connect the terminals 2a to the pads 3a.

The base plate 32 is not particularly limited in material or structure. Any known substrate can be used as the base plate 32. The base plate 32 may be flexible or rigid. The base plate 32 may have a single-layer or multilayer structure. The base plate 32 may contain wiring lines which are not shown. Furthermore, the base plate 32 is not particularly limited in shape.

The terminals 2a are arranged on the base plate 32. The terminals 2a are electrically connected to external terminals 2c with leads 2b. The terminals 2a, the leads 2b, and the external terminals 2c are collectively referred to as a base-side wiring pattern 2d. The base-side wiring pattern 2d is made of copper foil or the like.

The base plate 32 has a recessed section 32e for accommodating the semiconductor chip 3 and the insulating member 34. With reference to FIG. 5A, the recessed section 32e has substantially a rectangular shape in plan view and has an area slightly greater than that of the semiconductor chip 3 when viewed from above. A gap 32f having a loop shape in plan view is therefore present between the recessed section 32e and the semiconductor chip 3. The gap 32f is filled with the insulating member 34.

The recessed section 32e preferably has a depth less than or equal to the thickness of the semiconductor chip 3 exclusive of the pads 3a. That is, the recessed section 32e preferably has a depth less than or equal to the thickness of a main body section 3c included in the semiconductor chip 3. In particular, the depth of the recessed section 32e is preferably 30 to 50 μm. If the die attach film described in the first embodiment is used to join the semiconductor chip 3 to the base plate 32, the depth of the recessed section 32e may be adjusted to be less than or equal to the sum of the thickness of the main body section 3c of the semiconductor chip 3 and the thickness of the die attach film. In this case, in particular, the depth of the recessed section 32e is preferably 40 to 70 μm. With reference to FIG. 5B, the depth of the recessed section 32e is equal to the thickness of the main body section 3c of the semiconductor chip 3. Therefore, the first face 3b of the semiconductor chip 3 is flush with the upper face of the base plate 32 and the pads 3a seem to protrude from the upper face of the base plate 32.

The insulating member 34 is disposed in the gap 32f between the semiconductor chip 3 and the recessed section 32e so as to cover the steps between the semiconductor chip 3 and the base plate 32. With reference to FIG. 5B, the upper face 34a of the insulating member 34 is substantially flush with the upper face of the base plate 32. The upper face 34a of the insulating member 34 is not tilted with respect to the base plate 32, that is, the tilt angle of the upper face 34a thereof is substantially zero degree. This eliminates the steps between the upper face of the base plate 32 and the first face 3b of the semiconductor chip 3. The insulating member 34 is made of an insulating resin such as an epoxy resin and can be formed by, for example, a droplet-ejecting process.

The wiring pattern 5 extends on the upper face 34a of the insulating member 34 to electrically connect the terminals 2a to the pads. A material for forming the wiring pattern 5, as well as that described in the first embodiment, is not particularly limited. The wiring pattern 5 can be formed by, for example, a droplet-ejecting process.

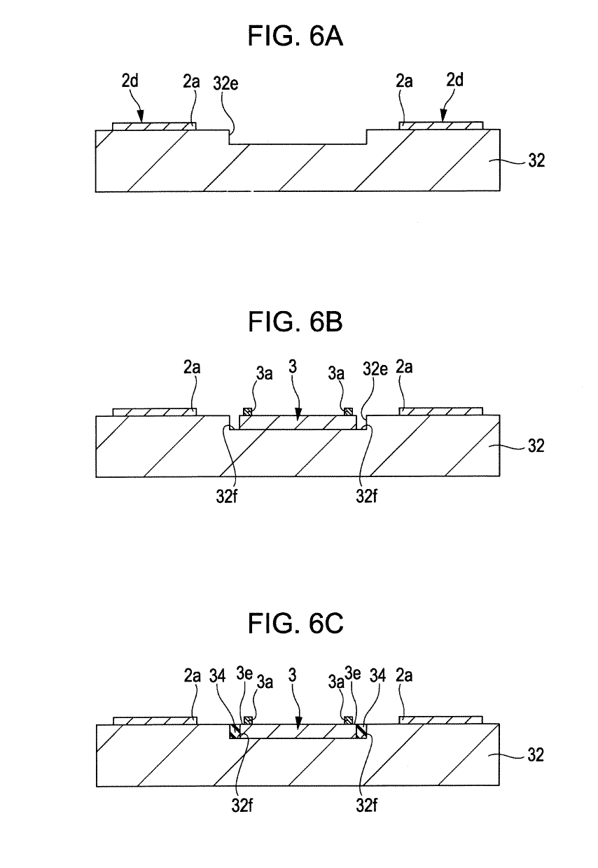

A method for manufacturing the semiconductor device 31 according to this embodiment will now be described. FIGS. 6A to 6C are illustrations showing steps included in the method.

In a first step, as shown in FIG. 6A, the base-side wiring pattern 2d is formed on the base plate 32 and the recessed section 32e is formed in the base plate 32. As shown in FIG. 6B, the semiconductor chip 3 is provided in the recessed section 32e.

In a second step, as shown in FIG. 6C, the insulating member 34 is provided in the gap 32f between the semiconductor chip 3 and the recessed section 32e so as to cover the steps between the semiconductor chip 3 and the base plate 32.

The insulating member 34 can be formed by, for example, a droplet-ejecting process. A procedure for forming the insulating member 34 by the droplet-ejecting process is as follows: a coating solution is prepared by dissolving an insulating material for forming the insulating member 34 in a solvent and then applied onto a region surrounding the semiconductor chip 3 using a droplet-ejecting head and the applied coating solution is dried. The application and drying of the coating solution are repeated several times, whereby the insulating material is grown. This allows the gap 32f between the semiconductor chip 3 and the recessed section 32e to be filled with the insulating member 34. The insulating material is retained by side faces of the semiconductor chip 3 and walls of the recessed section 32e and therefore prevented from spreading out of the recessed section 32e. Since the insulating material is retained in the recessed section 32e, the insulating material is prevented from extending to the terminals 2a; hence, the insulating material is grown to cover a marginal portion 3e of the semiconductor chip 3. The insulating member 34 is obtained as described above.

In a third step, the wiring pattern 5 is formed by a droplet-ejecting process, whereby the semiconductor device 31 is obtained as shown in FIG. 5A.

In the semiconductor device 31, the base plate 32 has the recessed section 32e for accommodating the semiconductor chip 3 and the insulating member 34 and the semiconductor chip 3 is fixed in the recessed section 32e with the insulating member 34; hence, the insulating member 34 has such a shape in cross section as shown in FIG. 5B and the upper face 34a of the insulating member 34 is flat and is not tilted. The insulating member 34 has such an appropriate shape, that is, the insulating member 34 has no portions with different tilt angles. This prevents the wiring pattern 5 from being broken.

Furthermore, since the marginal portion 3e of the semiconductor chip 3 is covered with the insulating member 34, a short circuit can be prevented from being caused between the wiring pattern 5 and the semiconductor chip 3.

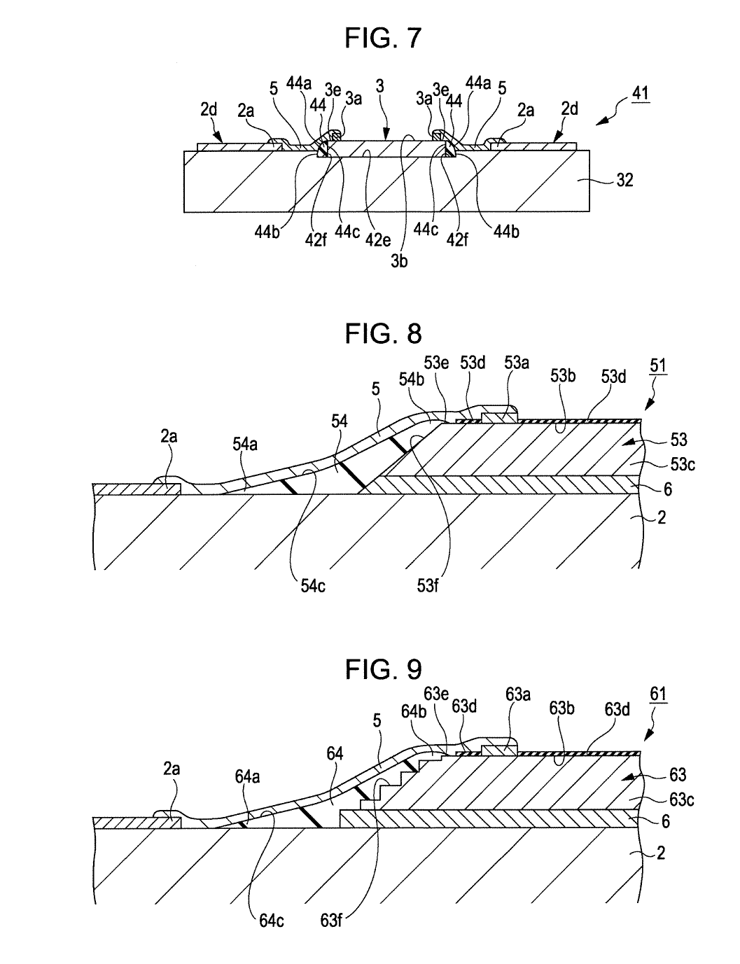

A modification of the semiconductor device 31 of this embodiment will now be described. FIG. 7 is a schematic sectional view of a semiconductor device 41 that is the modification of that semiconductor device 1.

This semiconductor device 41 is different from that semiconductor device 31 shown in FIGS. 5A and 5B in that this semiconductor device 41 has a recessed section 42e having a depth less than that of the recessed section 32e of that semiconductor device 31 and includes an insulating member 44 having a shape in cross section different from that of that insulating member 34. Components, included in this semiconductor device 41, other than this recessed section 42e and this insulating member 44 are the same as those included in that semiconductor device 31. The same components have the same reference numerals and will not be described in detail.

This semiconductor device 41 includes a base plate 32 and a semiconductor chip 3. A base-side wiring pattern 2d is disposed on this base plate 32. This recessed section 42e is present in this base plate 32 and accommodates this semiconductor chip 3 and this insulating member 44. This recessed section 42e has substantially a rectangular shape in plan view and has an area slightly greater than that of this semiconductor chip 3 when viewed from above. A gap 42f having a loop shape is therefore present between this recessed section 42e and this semiconductor chip 3. This gap 42f is filled with this insulating member 44.

This recessed section 42e preferably has a depth less than the thickness of this semiconductor chip 3 exclusive of pads 3a arranged on this semiconductor chip 3. That is, as shown in FIG. 7, this recessed section 42e preferably has a depth less than the thickness of a main body section 3c of this semiconductor chip 3. Therefore, a first face 3b of this semiconductor chip 3 seems to protrude from the upper face of this base plate 32.

This insulating member 44 is disposed in this gap 42f between this semiconductor chip 3 and this recessed section 42e so as to cover steps between this semiconductor chip 3 and this base plate 32. With reference to FIG. 7, the upper face 44a of this insulating member 44 is tilted and the upper face of this base plate 32 is connected to the first face 3b of this semiconductor chip 3 with the upper face 44a of this insulating member 44. This eliminates steps between the upper face of this base plate 32 and the first face 3b of this semiconductor chip 3. With reference to FIG. 7, this insulating member 44 has a first end portion 44b retained in this recessed section 42e and a second end portion 44c covering a marginal portion 3e of this semiconductor chip 3. This insulating member 44 is made of an insulating resin such as an epoxy resin and can be formed by, for example, a droplet-ejecting process.

A wiring pattern 5 extends on the upper face 44a of this insulating member 44 to electrically connect terminals 2a included in this base plate 32 to these pads 3a. Since the upper face of this base plate 32 is connected to the first face 3b of this semiconductor chip 3 with the upper face 44a of this insulating member 44, the wiring pattern 5 is prevented from being broken.

In this semiconductor device 41, this recessed section 42e, which accommodates this semiconductor chip 3 and this insulating member 44, is present in this base plate 32 and this semiconductor chip 3 is fixed in this recessed section 42e with this insulating member 44; hence, this insulating member 44 has such a shape in cross section as shown in FIG. 7 and the upper face 44a of this insulating member 44 is tilted and has no portions with different tilt angles but has a constant angle. This insulating member 44 has such an appropriate shape, that is, this insulating member 44 has no portions with different tilt angles. This prevents this wiring pattern 5 from being broken.

Furthermore, since the marginal portion 3e of this semiconductor chip 3 is covered with this insulating member 44, a short circuit can be prevented from being caused between this wiring pattern 5 and this semiconductor chip 3.

### Third Embodiment

A semiconductor device according to a third embodiment of the present invention will now be described. FIG. 8 is an enlarged sectional view of the semiconductor device. Some of components included in the semiconductor device shown in FIG. 8 are the same as those shown in FIGS. 1A to 1C. The same components have the same reference numerals and will not be described in detail.

With reference to FIG. 8, the semiconductor device is represented by reference numeral 51 and includes a base plate 2 including a plurality of terminals 2a; a semiconductor chip 53, mounted above the base plate 2, including a plurality of pads 53a arranged on a first face 53b of the semiconductor chip 53; an insulating slope member 54, disposed around the semiconductor chip 53, covering steps between the semiconductor chip 53 and the base plate 2; and a wiring pattern 5 extending on the insulating slope member 54 to electrically connect the terminals 2a to the pads 53a.

The base plate 2, as well as that described in the first embodiment, is not particularly limited in material or structure. Any known substrate can be used as the base plate 2. The base plate 2 may be flexible or rigid. The base plate 2 may have a single-layer or multilayer structure. The base plate 2 may contain wiring lines which are not shown. Furthermore, the base plate 2 is not particularly limited in shape.

The terminals 2a are arranged on the base plate 2. The terminals 2a are electrically connected to external terminals with leads which are not shown. The terminals 2a, the leads, and the external terminals are collectively referred to as a base-side wiring pattern 2d. The base-side wiring pattern 2d is made of copper foil or the like.

The semiconductor chip 53 includes a main body section 53c made of single-crystalline silicon doped with an impurity or the like and an integrated circuit section which is not shown and which is located in the main body section 53c. The integrated circuit section is connected to the pads 53a. The pads 53a are arranged on the first face 53b of the semiconductor chip 53. An insulating layer 53d extends over the first face 53b thereof except a marginal portion 53e of the first face 53b thereof. The main body section 53c is exposed at the marginal portion 53e thereof. The main body section 53c is made of single-crystalline silicon or the like and has a thickness of about 30 to 50 μm. The integrated circuit section is not particularly limited in configuration and may include, for example, an active element such as a transistor and a passive element such as a resistor, a coil, or a capacitor.

With reference to FIG. 8, the semiconductor chip 53 has a side face 53f which is tilted and which is adjacent to the insulating slope member 54. The tilt angle of the side face 53f of the semiconductor chip 53 is, for example, 30 to 60 degrees. The side face 53f of the semiconductor chip 53 is formed in a step of dicing a silicon wafer to prepare the semiconductor chip 53 using a dicing blade having a V-shaped edge. When the dicing blade has a 90-degree edge, the tilt angle of the side face 53f of the semiconductor chip 53 is about 45 degrees.

The semiconductor chip 53 is mounted above the base plate 2 in such a state that the pads 53a are directed in the direction opposite to the base plate 2. A die attach film 6 with a thickness of about 10 to 20 μm is disposed between the base plate 2 and the semiconductor chip 53. The base plate 2 and the semiconductor chip 53 are joined to each other with the die attach film 6. The height of the steps between the base plate 2 and the semiconductor chip 53 is equal to the sum of the thickness of the main body section 53c and the thickness of the die attach film 6 and is about 40 to 70 μm.

The insulating slope member 54 is disposed on the side face 53f of the semiconductor chip 53 to cover the steps between the semiconductor chip 53 and the base plate 2. With reference to FIG. 8, the insulating slope member 54 has a first end portion 54a located on the base plate 2 and a second end portion 54b covering the marginal portion 53e of the semiconductor chip 53. The insulating slope member 4 further has a slope 54c located between the first and second end portions 54a and 54b. The insulating slope member 54 is made of an insulating resin such as an epoxy resin and can be formed by, for example, a droplet-ejecting process.

The wiring pattern 5 extends on the slope 54c to electrically connect the terminals 2a to the pads 53a. A material for forming the wiring pattern 5, as well as that described in the first embodiment, is not particularly limited. The wiring pattern 5 can be formed by, for example, a droplet-ejecting process.

The semiconductor device 51 is manufactured by a method similar to the method for manufacturing the semiconductor device 1 of the first embodiment. In a first step, the base-side wiring pattern 2d is formed on the base plate 2 and the semiconductor chip 53 is then mounted above the base plate 2. The side face 53f of the semiconductor chip 53 is tilted. The side face 53f thereof is formed by dicing the silicon wafer as described above.

In a second step, the insulating slope member 54 is formed on the side face 53f of the semiconductor chip 53 so as to cover the steps between the semiconductor chip 53 and the base plate 2.

The insulating slope member 54 can be formed by, for example, a droplet-ejecting process. A procedure for forming the insulating slope member 54 by the droplet-ejecting process is as follows: a coating solution is prepared by dissolving an insulating material for forming the insulating slope member 54 in a solvent and then applied onto the side face 53f of the semiconductor chip 53 using a droplet-ejecting head and the applied coating solution is dried. The application and drying of the coating solution are repeated several times, whereby the insulating slope member 54 is formed as shown in FIG. 8. In this step, the coating solution remains on the side face 53f of the semiconductor chip 53 for a long time and therefore is prevented from spreading to the terminals 2a. However, the coating solution spreads to cover the marginal portion 53e of the semiconductor chip 53. The insulating slope member 4 is obtained as described above.

In a third step, the wiring pattern 5 is formed by a droplet-ejecting process, whereby the semiconductor device 51 can be obtained as shown in FIG. 8.

In the semiconductor device 51, since the side face 53f of the semiconductor chip 53 is adjacent to the insulating slope member 54 and is tilted, the coating solution used to form the insulating slope member 54 remains on the side face 53f of the semiconductor chip 53 for a long time; hence, the insulating slope member 54 is prevented from spreading and has an appropriate shape. This allows the insulating slope member 54 to have such a shape as shown in FIG. 8 and also allows the slope 54c to be flat and to have a constant tilt angle.

Since the insulating slope member 54 is formed on the tilted side face 53f of the semiconductor chip 53, the insulating slope member 54 has no portions with different tilt angles. This prevents the wiring pattern 5 from being broken.

Since the insulating slope member 54 is prevented from extending to the terminals 2a, the insulating slope member 54 can completely cover the marginal portion 53e of the first face 53b of the semiconductor chip 53. Although the main body section 53c of the semiconductor chip 53 that is made of single-crystalline silicon is exposed at the marginal portion 53e thereof before the insulating slope member 54 is formed, the exposed main body section 3c is covered with the second end portion 54b of the insulating slope member 54. This prevents a short circuit from being caused between the wiring pattern 5 and the semiconductor chip 53.

Since the insulating slope member 54 is prevented from extending to the terminals 2a, the terminals 2a can be formed close to the semiconductor chip 53. This leads to a reduction in the distance between the semiconductor chip 53 and the terminals 2a, resulting in a reduction in the size of the semiconductor device 51.

A modification of the semiconductor device 51 of this embodiment will now be described. FIG. 9 is an enlarged sectional view of a semiconductor device 61 that is the modification of that semiconductor device 51.

This semiconductor device 61 is different from that semiconductor device 51 shown in FIG. 8 in that this semiconductor device 61 includes a semiconductor chip 63 having a stepped side face 63f. Components, included in this semiconductor device 61, other than this semiconductor chip 63 are the same as those included in that semiconductor device 51. The same components have the same reference numerals and will not be described in detail.

With reference to FIG. 9, the side face 63f of this semiconductor chip 63 has five steps. These steps have a width of about 5 to 10 μm and a height equal to the quotient obtained by dividing the thickness of a main body section 63c included in this semiconductor chip 63 by the number of these steps. The side face 63f of this semiconductor chip 63 has a tilt angle of about 30 to 60 degrees. The side face 63f of this semiconductor chip 63 is formed in a step of dicing a silicon wafer to prepare this semiconductor chip 63. In the dicing step, a plurality of dicing blades having different edge widths are prepared and then used in decreasing order of edge width.

An insulating slope member 64 is disposed on the side face 63f of this semiconductor chip 63 and covers steps between this semiconductor chip 63 and a base plate 2. With reference to FIG. 9, this insulating slope member 64 has a first end portion 64a located on this base plate 2 and a second end portion 64b covering a marginal portion 63e of this semiconductor chip 63. This insulating slope member 64 further has a slope 64c located between these first and second end portions 64a and 64b. This insulating slope member 64 is made of an insulating resin such as an epoxy resin and can be formed by, for example, a droplet-ejecting process.

A wiring pattern 5 extends on the slope 64c of this insulating slope member 64 to electrically connect terminals 2a included in this base plate 2 to pads 63a included in this semiconductor chip 63. A material for forming this wiring pattern 5, as well as that described in the first embodiment, is not particularly limited. This wiring pattern 5 can be formed by, for example, a droplet-ejecting process.

This semiconductor device 61 is manufactured by the same method as that for manufacturing that semiconductor device 51 shown in FIG. 8.

In this semiconductor device 61, since the side face 63f of this semiconductor chip 63 is adjacent to this insulating slope member 64 and is stepped, the coating solution used to form this insulating slope member 64 remains on the side face 63f thereof for a long time. This prevents this insulating slope member 64 from spreading and also allows this insulating slope member 64 to have an appropriate shape. Therefore, this insulating slope member 64 has such a shape as shown in FIG. 9 and the slope 64c is flat and has a constant tilt angle.

Since the side face 63f of this semiconductor chip 63 is tilted and this insulating slope member 64 is disposed on the side face 63f thereof, this insulating slope member 64 has no portions with different tilt angles. This prevents this wiring pattern 5 from being broken.

Since this insulating slope member 64 is prevented from extending to these terminals 2a, this insulating slope member 64 can completely cover the marginal portion 63e of this semiconductor chip 63. Although a main body section 63c of this semiconductor chip 63 that is made of single-crystalline silicon is exposed at the marginal portion 63e thereof before this insulating slope member 64 is formed, the exposed main body section 63c is covered with the second end portion 64b of this insulating slope member 64. This prevents a short circuit from being caused between this wiring pattern 5 and this semiconductor chip 63.

Since this insulating slope member 64 is prevented from extending to these terminals 2a, these terminals 2a can be formed close to this semiconductor chip 63. This leads to a reduction in the distance between this semiconductor chip 63 and these terminals 2a, resulting in a reduction in the size of this semiconductor device 61.

### Fourth Embodiment

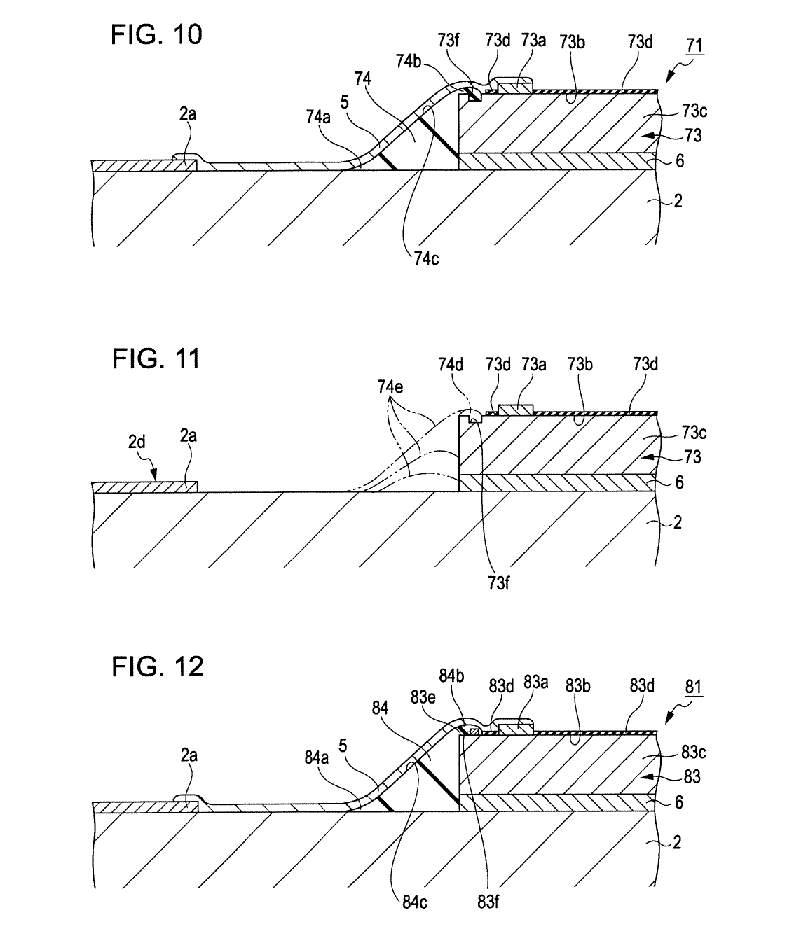

A semiconductor device according to a fourth embodiment of the present invention will now be described. FIG. 10 is an enlarged sectional view of the semiconductor device. Some of components included in the semiconductor device shown in FIG. 10 are the same as those shown in FIGS. 1A to 1C. The same components have the same reference numerals and will not be described in detail.

With reference to FIG. 10, the semiconductor device is represented by reference numeral 71 and includes a base plate 2 including a plurality of terminals 2a; a semiconductor chip 73, mounted above the base plate 2, including a plurality of pads 73a arranged on a first face 73b of the semiconductor chip 73; an insulating slope member 74, disposed around the semiconductor chip 73, covering steps between the semiconductor chip 73 and the base plate 2; and a wiring pattern 5 extending on the insulating slope member 74 to electrically connect the terminals 2a to the pads 73a.

The base plate 2, as well as that described in the first embodiment, is not particularly limited in material or structure. Any known substrate can be used as the base plate 2. The base plate 2 may be flexible or rigid. The base plate 2 may have a single-layer or multilayer structure. The base plate 2 may contain wiring lines which are not shown. Furthermore, the base plate 2 is not particularly limited in shape.

The terminals 2a are arranged on the base plate 2. The terminals 2a are electrically connected to external terminals with leads which are not shown. The terminals 2a, the leads, and the external terminals are collectively referred to as a base-side wiring pattern 2d. The base-side wiring pattern 2d is made of copper foil or the like.

The semiconductor chip 73 includes a main body section 73c made of single-crystalline silicon doped with an impurity or the like and an integrated circuit section which is not shown and which is located in the main body section 73c. The integrated circuit section is connected to the pads 73a. The pads 73a are arranged on the first face 73b of the semiconductor chip 73. An insulating layer 73d extends over the first face 73b thereof except a marginal portion 73e of the first face 73b thereof and the pads 73a. The semiconductor chip 73 has a chip-side retaining section 73f located in the marginal portion 73e. With reference to FIG. 10, the chip-side retaining section 73f has a groove extending outside the insulating layer 73d and has a loop shape so as to surround the insulating layer 73d. The groove has a depth of about 5 to 10 μm and a width of about 5 to 10 μm.

The main body section 73c is exposed at the marginal portion 73e. The main body section 73c is made of single-crystalline silicon or the like and has a thickness of about 30 to 50 μm. The integrated circuit section is not particularly limited in configuration and may include, for example, an active element such as a transistor and a passive element such as a resistor, a coil, or a capacitor. The semiconductor chip 73 is mounted above the base plate 2 in such a state that the pads 73a are directed in the direction opposite to the base plate 2. A die attach film 6 with a thickness of about 10 to 20 μm is disposed between the base plate 2 and the semiconductor chip 73. The base plate 2 and the semiconductor chip 73 are joined to each other with the die attach film 6.

The height of the steps between the base plate 2 and the semiconductor chip 73 is equal to the sum of the thickness of the main body section 3c and the thickness of the die attach film 6 and is about 40 to 70 μm.

The insulating slope member 74 is disposed around the semiconductor chip 73 to cover the steps between the semiconductor chip 73 and the base plate 2. With reference to FIG. 10, the insulating slope member 74 has a first end portion 74a located on the base plate 2 and a second end portion 74b which covers the marginal portion 73e of the semiconductor chip 73 and which is retained in the groove. The insulating slope member 74 further has a slope 74c located between the first and second end portions 74a and 74b. The insulating slope member 74 is made of an insulating resin such as an epoxy resin and can be formed by, for example, a droplet-ejecting process.

The wiring pattern 5 extends on the slope 74c to electrically connect the terminals 2a to the pads 73a. A material for forming the wiring pattern 5, as well as that described in the first embodiment, is not particularly limited. The wiring pattern 5 can be formed by, for example, a droplet-ejecting process.

A method for manufacturing the semiconductor device 71 will now be described. FIG. 11 is an illustration showing a step included in the method.

In a first step, the base-side wiring pattern 2d is formed on the base plate 2 and the semiconductor chip 73 is then mounted above the base plate 2. The semiconductor chip 73 has the chip-side retaining section 73f, including the groove, located in the marginal portion 73e of the first face 73b of the semiconductor chip 73. The chip-side retaining section 73f can be formed by, for example, a lithographic process in a step of preparing the semiconductor chip 73.

In a second step, as shown in FIG. 11, the insulating slope member 74 is provided around the semiconductor chip 73 so as to cover the steps between the semiconductor chip 73 and the base plate 2.

The insulating slope member 74 can be formed by, for example, a droplet-ejecting process. A procedure for forming the insulating slope member 74 by the droplet-ejecting process is as follows: a coating solution 74d is prepared by dissolving an insulating material for forming the insulating slope member 74 in a solvent and then applied onto the surroundings of the semiconductor chip 73 using a droplet-ejecting head. In this procedure, the coating solution 74d is primarily applied onto the chip-side retaining section 73f and then applied onto a region surrounding the semiconductor chip 73. The applied coating solution 74d is dried. Furthermore, the coating solution 74d is applied onto the region surrounding the semiconductor chip 73. The application and drying of the coating solution 74d are repeated several times, whereby the insulating material is grown as shown in FIG. 11. A portion of the insulating material that is located on the chip-side retaining section 73f is incorporated with a portion of the insulating material that is located on the region surrounding the semiconductor chip 73 such that the insulating slope member 74 covers the steps between the semiconductor chip 73 and the base plate 2. In this step, the insulating material is retained in the groove or by the chip-side retaining section 73f; hence, the coating solution 74d is prevented from spreading to the terminals 2a. Since the coating solution 74d is primarily applied onto the chip-side retaining section 73f, the marginal portion 73e of the semiconductor chip 73 is covered with the insulating slope member 74. The insulating slope member 74 is obtained as described above.

In a third step, the wiring pattern 5 is formed by a droplet-ejecting process, whereby the semiconductor device 71 can be obtained as shown in FIG. 10.

In the semiconductor device 71, since the chip-side retaining section 73f, including the groove, for retaining the insulating slope member 74 is disposed in the first face 73b of the semiconductor chip 73, the insulating slope member 74 completely covers the marginal portion 73e of the first face 73b thereof. Therefore, the insulating slope member 74 has an appropriate shape and also has no portions with different tilt angles. This prevents the wiring pattern 5 from being broken.

Since the insulating slope member 74 has such an appropriate shape and completely covers the marginal portion 73e of the first face 73b of the semiconductor chip 73, a short circuit can be prevented from being caused between the wiring pattern 5 and the semiconductor chip 73.

A modification of the semiconductor device 71 of this embodiment will now be described. FIG. 12 is an enlarged sectional view of a semiconductor device 81 that is the modification of that semiconductor device 71.

This semiconductor device 81 is different from that semiconductor device 71 shown in FIG. 10 in that this semiconductor device 81 includes a chip-side retaining section 83f including bumps. Components, included in this semiconductor device 81, other than this base-side retaining section 83f are the same as those included in that semiconductor device 71. The same components have the same reference numerals and will not be described in detail.

With reference to FIG. 12, a semiconductor chip 83 includes a main body section 83c made of single-crystalline silicon doped with an impurity or the like and an integrated circuit section which is not shown and which is located in this main body section 83c. This integrated circuit section is connected to pads 83a. These pads 83a are arranged on a first face 83b of this semiconductor chip 83. An insulating layer 83d extends over the first face 83b thereof except a marginal portion 83e of the first face 83b thereof and these pads 73a. This chip-side retaining section 83f is located in the marginal portion 83e thereof. With reference to FIG. 12, this chip-side retaining section 83f includes the bumps arranged outside this insulating layer 83d and has a loop shape so as to surround this insulating layer 83d. The bumps have a height of about 5 to 10 μm and a width of about 5 to 10 μm. The bumps are made of a conductive material such as Cu and can be formed by a photolithographic process in a step of preparing this semiconductor chip 83.

This main body section 83c is exposed at this marginal portion 83e including this chip-side retaining section 83f. This main body section 83c is made of single-crystalline silicon and has a thickness of about 30 to 50 μm.

An insulating slope member 84 is disposed around this semiconductor chip 83 to cover steps between this semiconductor chip 83 and a base plate 2. With reference to FIG. 12, this insulating slope member 84 has a first end portion 84a disposed on this base plate 2 and a second end portion 84b which covers this marginal portion 83e and which is retained by the bumps. This insulating slope member 84 further has a slope 84c located between these first and second end portions 84a and 84b. This insulating slope member 84 is made of an insulating resin such as an epoxy resin and can be formed by, for example, a droplet-ejecting process.

A wiring pattern 5 extends on this slope 84c to electrically connect these terminals 2a to these pads 83a. A material for forming this wiring pattern 5, as well as that described in the first embodiment, is not particularly limited. This wiring pattern 5 can be formed by, for example, a droplet-ejecting process.

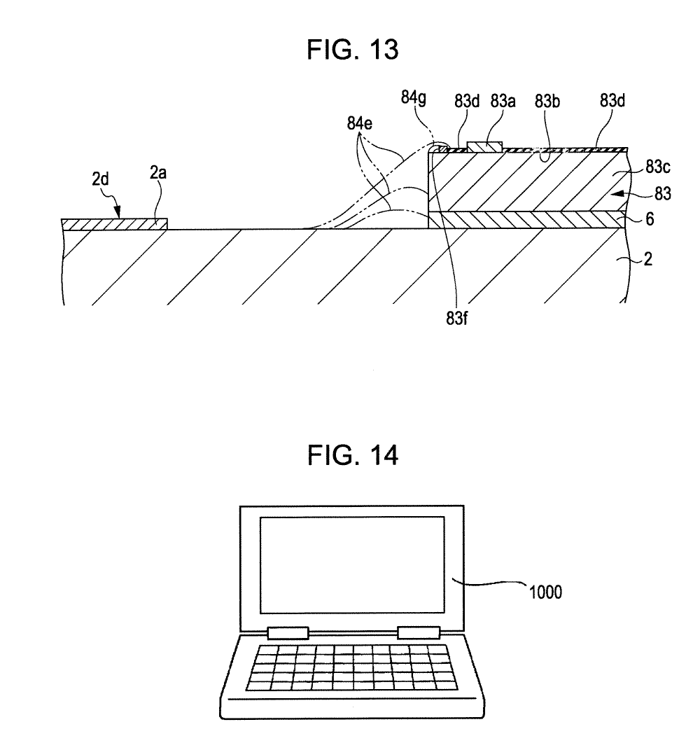

A method for manufacturing this semiconductor device 81 will now be described. FIG. 13 is an illustration showing a step included in this method.

In a first step, a base-side wiring pattern 2d is formed on this base plate 2 and this semiconductor chip 83 is then mounted above this base plate 2. This semiconductor chip 83 has this chip-side retaining section 83f, including these bumps, located in the marginal portion 83e of the first face 83b of this semiconductor chip 83. This chip-side retaining section 83f can be formed by, for example, a lithographic process in a step of preparing this semiconductor chip 83.

In a second step, as shown in FIG. 13, this insulating slope member 84 is formed around this semiconductor chip 83 so as to cover the steps between this semiconductor chip 83 and this base plate 2.

This insulating slope member 84 can be formed by, for example, a droplet-ejecting process. A procedure for forming this insulating slope member 84 by the droplet-ejecting process is as follows: a coating solution 84g is prepared by dissolving an insulating material for forming this insulating slope member 84 in a solvent and then applied onto the surroundings of this semiconductor chip 83 using a droplet-ejecting head. In this procedure, this coating solution 84g is primarily applied onto this chip-side retaining section 83f and then applied onto a region surrounding this semiconductor chip 83. This applied coating solution 84g is dried. Furthermore, this coating solution 84g is applied onto the region surrounding this semiconductor chip 83. The application and drying of this coating solution 84g are repeated several times, whereby this insulating material is grown as shown in FIG. 13. A portion of this insulating material that is located on this chip-side retaining section 83f is incorporated with a portion of this insulating material that is located on the region surrounding this semiconductor chip 83 such that this insulating slope member 84 covers the steps between this semiconductor chip 83 and this base plate 2. In this step, this insulating material is retained in this groove or by this chip-side retaining section 83f; hence, this coating solution 84g is prevented from spreading to these terminals 2a. Since this coating solution 84g is primarily applied onto this chip-side retaining section 83f, the marginal portion 83e of this semiconductor chip 83 is covered with this insulating slope member 84. This insulating slope member 84 is obtained as described above.

In a third step, this wiring pattern 5 is formed by a droplet-ejecting process, whereby this semiconductor device 81 can be obtained as shown in FIG. 12.

This semiconductor device 81 has same advantages as those of that semiconductor device 71. In this semiconductor device 81, this chip-side retaining section 83f may include a guard ring, instead of these bumps, disposed on this semiconductor chip 83. This eliminates the formation of these bumps, resulting in the simplification of this manufacturing method.

### Fifth Embodiment

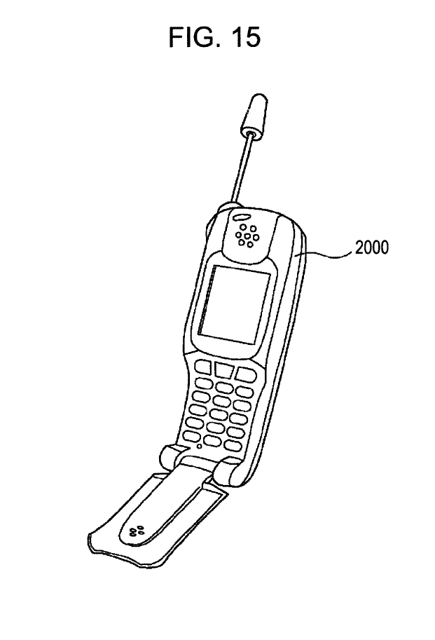

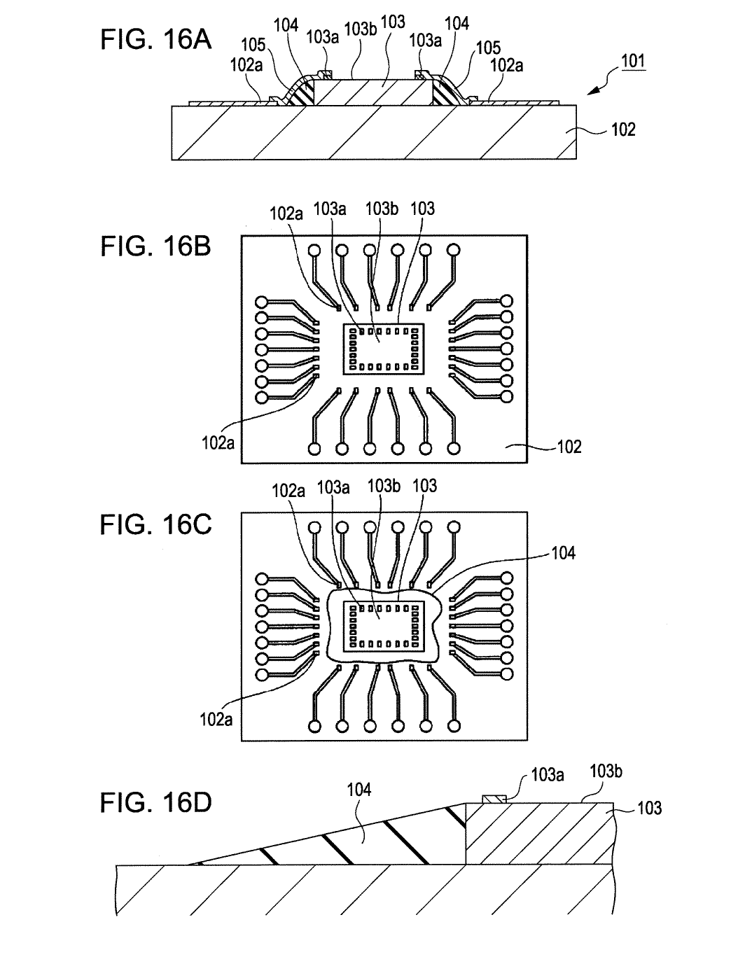

A fifth embodiment of the present invention provides an electronic apparatus. The electronic apparatus includes the semiconductor device according to any one of the above embodiments. FIG. 14 shows a notebook-type personal computer 1000 that is an example of the electronic apparatus. FIG. 15 shows a mobile phone 2000 that is another example of the electronic apparatus.

The scope of the present invention is not limited to the above embodiments. For example, the techniques described in the first and third embodiments may be used in combination.

What is claimed is:

1. A semiconductor device comprising:
a base plate including a plurality of terminals;
a semiconductor chip, mounted above the base plate, including a plurality of pads arranged on a face of the semiconductor chip;
an insulating slope member, disposed around the semiconductor chip, covering steps between the semiconductor chip and the base plate; and
a wiring pattern extending on the insulating slope member to electrically connect the terminals to the pads,
wherein the base plate has a base-side retaining section for retaining the insulating slope member.

2. The semiconductor device according to claim 1, wherein the base-side retaining section has a groove or bumps.

3. The semiconductor device according to claim 1, wherein the base-side retaining section is disposed between the terminals and the pads.

4. A semiconductor device comprising:
a base plate including a plurality of terminals;
a semiconductor chip, mounted above the base plate, including a plurality of pads arranged on a face of the semiconductor chip;
an insulating member, disposed around the semiconductor chip, covering steps between the semiconductor chip and the base plate; and
a wiring pattern extending on the insulating slope member to electrically connect the terminals to the pads,
wherein the base plate has a recessed section for accommodating the semiconductor chip and the insulating member.

5. The semiconductor device according to claim 4, wherein the recessed section has a depth less than or equal to the thickness of the semiconductor chip.

6. A semiconductor device comprising:
a base plate including a plurality of terminals;
a semiconductor chip, mounted above the base plate, including a plurality of pads arranged on a face of the semiconductor chip;
an insulating slope member, disposed around the semiconductor chip, covering steps between the semiconductor chip and the base plate; and
a wiring pattern extending on the insulating slope member to electrically connect the terminals to the pads,
wherein the semiconductor chip has a side face which is adjacent to the insulating slope member and which is tilted or stepped and the insulating slope member is disposed on the side face of the insulating slope member.

7. A semiconductor device comprising:
a base plate including a plurality of terminals;
a semiconductor chip, mounted above the base plate, including a plurality of pads arranged on a face of the semiconductor chip;
an insulating slope member, disposed around the semiconductor chip, covering steps between the semiconductor chip and the base plate; and
a wiring pattern extending on the insulating slope member to electrically connect the terminals to the pads,
wherein the semiconductor chip has a chip-side retaining section, disposed on the face of the semiconductor chip, for retaining the insulating slope member.

8. The semiconductor device according to claim 7, wherein the base-side retaining section has a groove or bumps.

9. The semiconductor device according to claim 7, wherein the chip-side retaining section has a guard ring disposed on the face of the semiconductor chip.

10. The semiconductor device according to claim 7, wherein the base-side retaining section is located outside the pads.

11. A method for manufacturing a semiconductor device comprising:
mounting a semiconductor chip including a plurality of pads above a base plate including a plurality of terminals, the pads being arranged on a face of the semiconductor chip;
forming an insulating slope member around the semiconductor chip such that the insulating slope member covers steps between the semiconductor chip and the base plate; and
forming a wiring pattern on the insulating slope member such that the wiring pattern electrically connects the terminals to the pads,
wherein the base plate has a base-side retaining section for retaining the insulating slope member and the insulating slope member is retained by the base-side retaining section when the insulating slope member is formed.

12. A method for manufacturing a semiconductor device comprising:
mounting a semiconductor chip including a plurality of pads above a base plate including a plurality of terminals, the pads being arranged on a face of the semiconductor chip;
forming an insulating member around the semiconductor chip such that the insulating member covers steps between the semiconductor chip and the base plate; and
forming a wiring pattern on the insulating member such that the wiring pattern electrically connects the terminals to the pads,
wherein the base plate has a recessed section for accommodating the semiconductor chip and the insulating member and the insulating member is provided in a gap between the recessed section and the semiconductor chip.

13. A method for manufacturing a semiconductor device comprising:
mounting a semiconductor chip including a plurality of pads above a base plate including a plurality of terminals, the pads being arranged on a face of the semiconductor chip;
forming an insulating slope member around the semiconductor chip such that the insulating slope member covers steps between the semiconductor chip and the base plate; and
forming a wiring pattern on the insulating slope member such that the wiring pattern electrically connects the terminals to the pads,
wherein the semiconductor chip has a side face which is adjacent to the insulating slope member and which is tilted or stepped and the insulating slope member is disposed on the side face of the insulating slope member.

14. A method for manufacturing a semiconductor device comprising:
mounting a semiconductor chip including a plurality of pads above a base plate including a plurality of terminals, the pads being arranged on a face of the semiconductor chip;
forming an insulating slope member around the semiconductor chip such that the insulating slope member covers steps between the semiconductor chip and the base plate; and
forming a wiring pattern on the insulating slope member such that the wiring pattern electrically connects the terminals to the pads,
wherein the semiconductor chip has a chip-side retaining section, disposed on the face of the semiconductor chip, for retaining the insulating slope member and the insulating slope member is retained by the chip-side retaining section when the insulating slope member is formed.
